(19) United States
(12) Patent Application Publication
(10) Pub. No.: US 2025/0038146 A1
(43) Pub. Date: Jan. 30, 2025

(54) SEMICONDUCTOR DEVICE

(71) Applicant: FUJI ELECTRIC CO., LTD., Kawasaki-shi (JP)

(72) Inventor: Yushi SATO, Matsumoto-city (JP)

(73) Assignee: FUJI ELECTRIC CO., LTD., Kawasaki-shi (JP)

(21) Appl. No.: 18/677,690

(22) Filed: May 29, 2024

(30) Foreign Application Priority Data
Jul. 25, 2023 (JP) 2023-120657

(51) Int. Cl. H01L 23/00; H01L 23/373; H01L 23/473; H01L 25/07

(52) U.S. Cl. CPC H01L 24/32; H01L 23/3735; H01L 23/473; H01L 24/29; H01L 24/37; H01L 24/40; H01L 24/45; H01L 24/48; H01L 24/73; H01L 25/072; H01L 2224/29111; H01L 2224/32225; H01L 2224/37147; H01L 2224/40225; H01L 2224/45147; H01L 2224/48225; H01L 2224/73213; H01L 2224/73221; H01L 2224/73263; H01L 2224/73265; H01L 2924/1203; H01L 2924/13055; H01L 2924/35121

(57) ABSTRACT

A semiconductor device includes: a semiconductor chip including upper and lower surfaces and transistor regions and diode regions being arranged alternately with one another along the upper and lower surfaces; a lead frame containing copper disposed on the upper surface of the semiconductor chip; a plating layer containing nickel disposed on a semiconductor chip-side surface of the lead frame; a solder layer that contains tin and bonds the upper surface of the semiconductor chip to the plating layer; an insulated circuit board that is disposed on the lower surface of the semiconductor chip and has a wiring layer containing copper disposed on a semiconductor chip-side surface thereof; a plating layer containing nickel that is disposed on a semiconductor chip-side surface of the wiring layer; and a solder layer containing tin that bonds the lower surface of the semiconductor chip to the plating layer.

### CROSS-REFERENCE TO RELATED APPLICATION

This application is based upon and claims the benefit of priority of the prior Japanese Patent Application No. 2023-120657, filed on Jul. 25, 2023, the entire contents of which are incorporated herein by reference.

### BACKGROUND OF THE INVENTION

### 1. Field of the Invention

The embodiment discussed herein relates to a semiconductor device.

### 2. Background of the Related Art

There is known a semiconductor power module with a configuration where an insulating substrate and a lead frame are soldered to a semiconductor chip (see, for example, International Publication Pamphlet No. WO 2016/079881). A semiconductor device equipped with a wiring layer provided on an insulating substrate, a covering layer that covers the wiring layer so as to expose part of an upper surface of the wiring layer at an opening, and a bonding layer that uses solder and is bonded to the wiring layer at the opening has also been proposed (see, for example, International Publication Pamphlet No. WO 2022/244395). One example of a power device element used in a semiconductor power module is a reverse-conducting insulated gate bipolar transistor (RC-IGBT) (see, for example, Yushi Sato et al., “Advantage of Lead-Frame Wiring and High Reliable to Electromigration Package for High Power Density Automotive Power Module”, PCIM Europe 2023, May 2023).

### SUMMARY OF THE INVENTION

According to one aspect, there is provided a semiconductor device, including: a semiconductor chip having an upper surface and a lower surface opposite to each other, and including transistor regions and diode regions that are arranged alternately with one another in a direction along the upper surface and the lower surface; a lead frame that contains copper and is disposed on the upper surface of the semiconductor chip; a first plating layer that contains nickel and is disposed on a semiconductor chip-side surface of the lead frame; a first solder layer that contains tin and bonds the upper surface of the semiconductor chip to the first plating layer; an insulated circuit board that is disposed on the lower surface of the semiconductor chip and has a wiring layer, which contains copper, disposed on a semiconductor chip-side surface thereof; a second plating layer that contains nickel and is disposed on a semiconductor chip-side surface of the wiring layer; and a second solder layer that contains tin and bonds the lower surface of the semiconductor chip to the second plating layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to an embodiment;

FIG. 2 is a side view of the semiconductor device according to the embodiment;

FIG. 3 is a plan view of a semiconductor unit included in the semiconductor device;

FIG. 4 is a cross-sectional view of the semiconductor unit included in the semiconductor device;

FIG. 5 is a plan view of a semiconductor chip;

FIG. 6 is a diagram useful in explaining electromigration;

FIG. 7 depicts a comparative example of a cross-sectional structure of the semiconductor unit;

FIG. 8 is a first diagram depicting one example of formation of a tin-copper alloy layer in the comparative example;

FIG. 9 is a second diagram depicting one example of formation of a tin-copper alloy layer in the comparative example;

FIG. 10 depicts a first example of formation of plating layers in the semiconductor unit;

FIG. 11 depicts a second example of formation of plating layers in the semiconductor unit;

FIG. 12 depicts a third example of formation of plating layers in the semiconductor unit;

FIG. 13 depicts a fourth example of formation of plating layers in the semiconductor unit; and

FIG. 14 depicts a fifth example of formation of plating layers in the semiconductor unit.

### DETAILED DESCRIPTION OF THE INVENTION

An embodiment will be described below with reference to the accompanying drawings. Note that in the following description, the expressions “front surface” and “upper surface” refer to an X-Y surface that faces upward (in the +Z direction) for the illustrated power converter apparatus. In the same way, the expression “up” refers to an upward (or +Z) direction for the illustrated power converter apparatus. The expressions “rear surface” and “lower surface” refer to an X-Y surface that faces downward (in the −Z direction) for the illustrated power converter apparatus. In the same way, the expression “down” refers to a downward (or −Z) direction for the illustrated power converter apparatus. These expressions are used to refer to the same directions in other drawings, as appropriate. The expressions “front surface”, “upper surface”, “up”, “rear surface”, “lower surface”, “down”, and “side surface” are merely convenient expressions used to specify relative positional relationships, and are not intended to limit the technical scope of the present embodiments. As one example, “up” and “down” do not necessarily mean directions that are perpendicular to the ground. That is, the “up” and “down” directions are not limited to the direction of gravity.

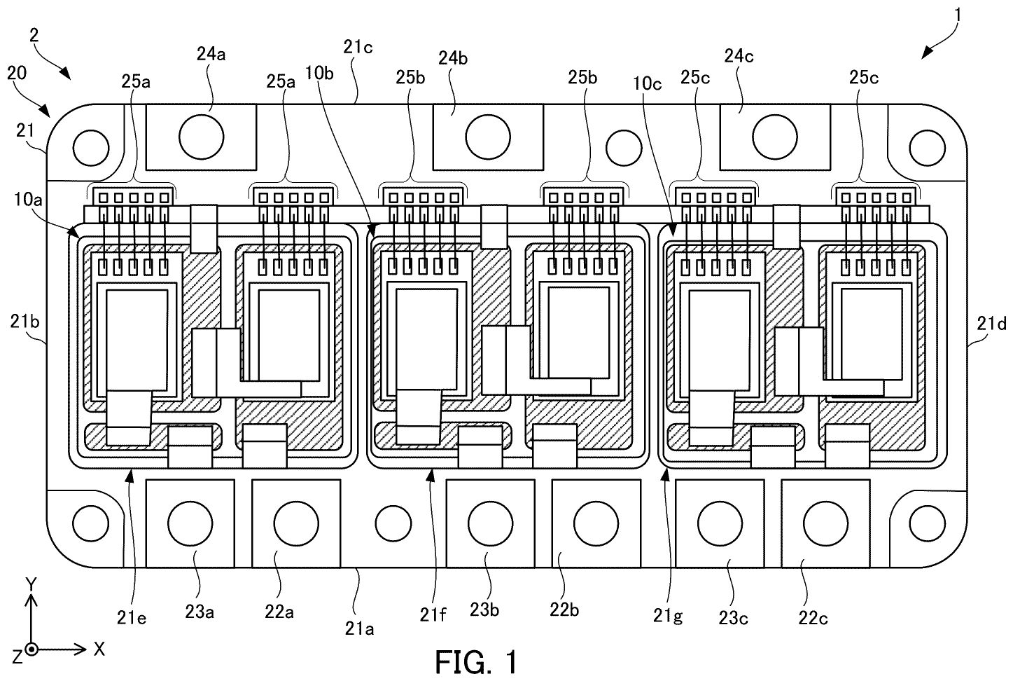

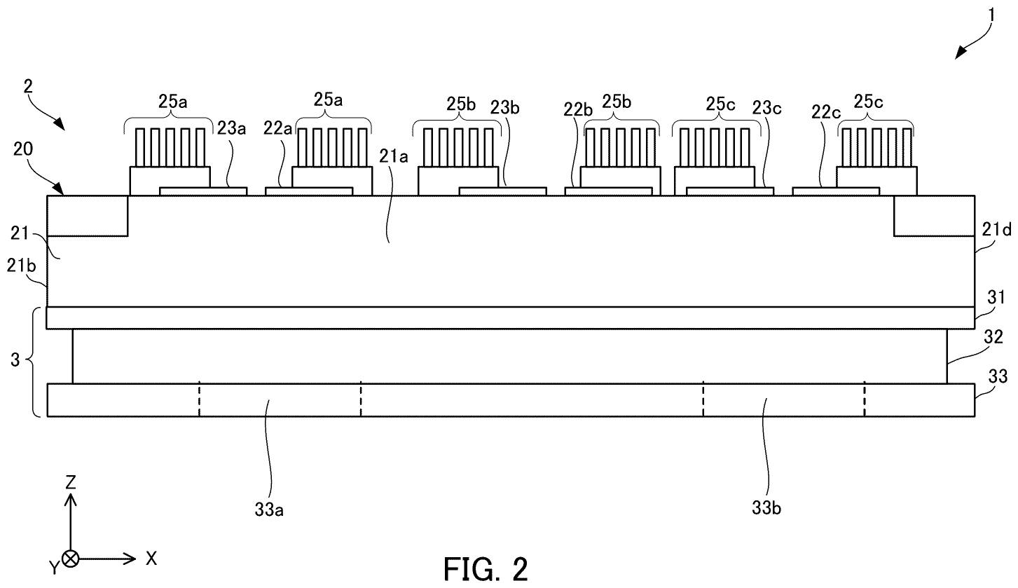

First, one example of the overall configuration of a semiconductor device according to an embodiment will be described using FIGS. 1 and 2. FIG. 1 is a plan view of a semiconductor device according to an embodiment. FIG. 2 is a side view of the semiconductor device according to the embodiment. Note that FIG. 2 is a side view of the semiconductor device 1 appearing in FIG. 1 when looking in the Y direction.

The semiconductor device 1 includes a semiconductor module 2 and a cooling device 3. The semiconductor module 2 includes semiconductor units 10a, 10b, and 10c, and a case 20 that houses the semiconductor units 10a, 10b, and 10c. The semiconductor units 10a, 10b, and 10c are disposed in a line on the cooling device 3. The case 20 is disposed on the cooling device 3, so that the semiconductor units 10a, 10b, and 10c are housed inside the case 20. The semiconductor units 10a, 10b, and 10c housed inside the case 20 are encapsulated with an encapsulating member (not illustrated).

Note that the semiconductor units 10a, 10b, and 10c all have the same configuration. When not distinguishing between them, the semiconductor units 10a, 10b, and 10c are collectively referred to as the “semiconductor units 10”. The semiconductor units 10 will be described in detail later.

The case 20 includes an outer frame 21, first connection terminals 22a, 22b, and 22c, second connection terminals 23a, 23b, and 23c, a U-phase output terminal 24a, a V-phase output terminal 24b, a W-phase output terminal 24c, and control terminals 25a, 25b, and 25c.

The outer frame 21 is rectangular in shape in plan view, and is surrounded on four sides by side walls 21a, 21b, 21c, and 21d. Note that the side walls 21a and 21c are the long sides of the outer frame 21, and the side walls 21b and 21d are the short sides of the outer frame 21. In plan view, the corners where the side walls 21a, 21b, 21c, and 21d are joined do not need to be right-angled. As one example, these joins between the side walls may be rounded as depicted in FIG. 1. A rear surface of the outer frame 21 (that is, the rear surfaces of the side walls 21a, 21b, 21c, and 21d) may lie on the same plane and may be parallel to the X-Y plane.

The outer frame 21 includes unit housing portions 21e, 21f, and 21g that are aligned along the side walls 21a and 21c (that is, in the ±X direction) and located in the center in the ±Y direction of the front surface. In plan view of the front surface of the outer frame 21, these unit housing portions 21e, 21f, and 21g are defined to be rectangular in shape and are open. The semiconductor units 10a, 10b, and 10c are housed in these unit housing portions 21e, 21f, and 21g, respectively. Accordingly, the unit housing portions 21e, 21f, and 21g may be sized so as to be capable of housing the semiconductor units 10a, 10b, and 10c.

In plan view, the outer frame 21 is provided with the first connection terminals 22a, 22b, and 22c and the second connection terminals 23a, 23b, and 23c which are aligned along the side wall 21a (that is, along the ±X direction) on the side wall 21a side of the front surface. The first connection terminals 22a, 22b, and 22c are positive input terminals (or “P terminals”), and the second connection terminals 23a, 23b, and 23c are negative input terminals (or “N terminals”).

The outer frame 21 is also provided with the U-phase output terminal 24a, the V-phase output terminal 24b, and the W-phase output terminal 24c which are aligned along the side wall 21c (that is, along the ±X direction) on the side wall 21c side of the front surface. In this configuration, the first connection terminal 22a and the second connection terminal 23a are provided on one side of the unit housing portion 21e with the U-phase output terminal 24a on the other side. Similarly, the first connection terminal 22b and the second connection terminal 23b are provided on one side of the unit housing portion 21f with the V-phase output terminal 24b on the other side. The first connection terminal 22c and the second connection terminal 23c are provided on one side of the unit housing portion 21g with the W-phase output terminal 24c on the other side.

The control terminals 25a, 25b, and 25c are provided on the front surface of the outer frame 21, in plan view, between the unit housing portions 21e, 21f, and 21g and the U-phase output terminal 24a, the V-phase output terminal 24b, and the W-phase output terminal 24c, respectively. Like the example depicted in FIGS. 1 and 2, the control terminals 25a, 25b, and 25c may each be divided into two for the unit housing portions 21e, 21f, and 21g, respectively.

The outer frame 21 described above including the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c is integrally formed by injection molding using thermoplastic resin. In this manner, the case 20 is configured. As examples, the thermoplastic resin is polyphenylene sulfide resin, polybutylene terephthalate resin, polybutylene succinate resin, polyamide resin, or acrylonitrile butadiene styrene resin.

The first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, 25c are made of a metal with superior electrical conductivity. Example metals include copper, aluminum, or an alloy containing at least one of these metals as a main component. A plating process may be performed on the surfaces of the first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c. Example plating materials include nickel, nickel-phosphorus alloy, and nickel-boron alloy. The first connection terminals 22a, 22b, and 22c, the second connection terminals 23a, 23b, and 23c, the U-phase output terminal 24a, the V-phase output terminal 24b, the W-phase output terminal 24c, and the control terminals 25a, 25b, and 25c that have been plated have improved corrosion resistance.

Note that in the following description, when no particular distinction is made between them, the first connection terminals 22a, 22b, and 22c are referred to as the “first connection terminals 22”. In the same way, the second connection terminals 23a, 23b, and 23c are collectively referred to as the “second connection terminals 23”, and the U-phase output terminal 24a, the V-phase output terminal 24b, and the W-phase output terminal 24c are collectively referred to as the “output terminals 24”. The control terminals 25a, 25b, and 25c are collectively referred to as the “control terminals 25”.

The encapsulating member that encapsulates the semiconductor units 10a, 10b, and 10c may be a thermosetting resin. Example thermosetting resins include epoxy resin, phenol resin, maleimide resin, and polyester resin. Here, epoxy resin is preferably used. Filler may also be added to the encapsulating member. The filler may be a ceramic that has insulation properties and high thermal conductivity.

The cooling device 3 includes an inlet 33a through which a coolant flows into the cooling device 3 and an outlet 33b through which coolant that has passed through the inside flows out to the outside. The cooling device 3 cools the semiconductor units 10 by carrying heat away from the semiconductor units 10 via the coolant. Examples of the coolant used here include water, antifreeze (an aqueous solution of ethylene glycol), and long-life coolant. The cooling device 3 may also include a pump and a heat radiating device (or “radiator”). The pump circulates the coolant by introducing the coolant into the inlet 33a of the cooling device 3 and causing coolant that has flowed out from the outlet 33b to flow back into the inlet 33a. The heat radiating device receives the coolant that has flowed out from the cooling device 3 and radiates the heat that has been transferred from the semiconductor units 10 to the coolant to the outside.

This cooling device 3 includes a top plate 31, a side wall 32 that is connected in a ring shape to the rear surface of the top plate 31, and a cooling bottom plate 33 that faces the top plate 31 and is connected to the rear surface of the side wall 32. In plan view, the top plate 31 is rectangular in shape and surrounded on four sides by long sides and short sides. In plan view, the corners of the top plate 31 may be rounded. The semiconductor units 10a, 10b, and 10c are bonded to the front surface of the top plate 31 along the ±X direction. The side wall 32 is continuously formed in a ring shape on the rear surface of the top plate 31. The cooling bottom plate 33 is formed as a flat plate, and has the same shape as the top plate 31 in plan view. The corners of the cooling bottom plate 33 may also be rounded.

A plurality of heat radiating fins (not illustrated) are formed in a region on the rear surface of the top plate 31 corresponding to regions where the semiconductor units 10a, 10b, and 10c are disposed. As one example, each heat radiating fin is shaped as a flat plate that is parallel to the X-Z plane and is disposed in parallel with the Y direction. The inlet 33a and the outlet 33b, through which the coolant flows respectively in and out of the cooling device 3, are formed in the bottom surface of the cooling bottom plate 33. Coolant distributing heads are attached via ring-shaped rubber packing to the inlet 33a and the outlet 33b in sealed regions that surround the inlet 33a and the outlet 33b. Coolant pipes that are connected to the pump are attached to these coolant distributing heads.

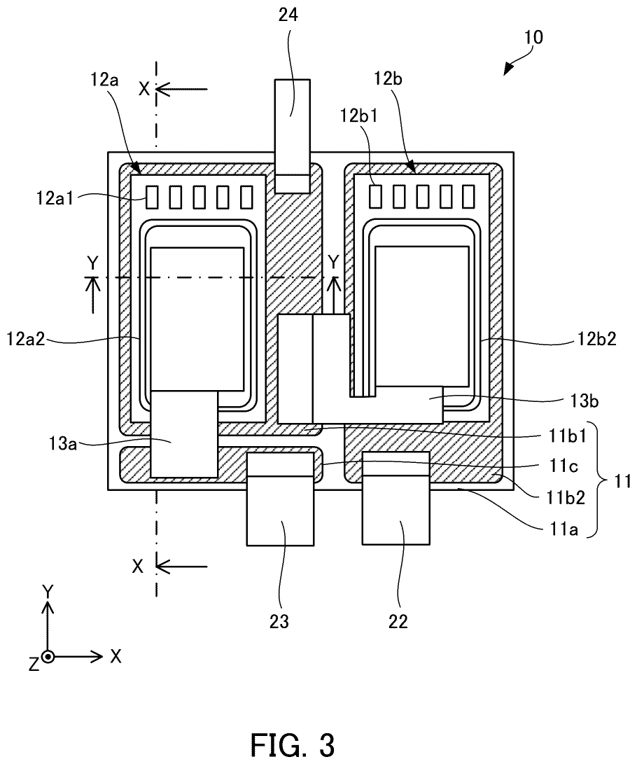

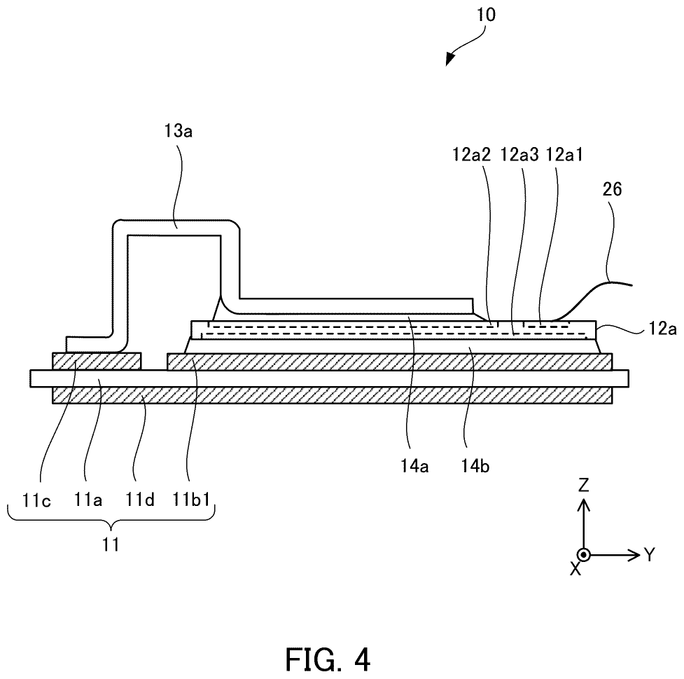

Next, the semiconductor units 10 will be described with reference to FIGS. 3 and 4. FIG. 3 is a plan view of a semiconductor unit included in the semiconductor device. FIG. 4 is a cross-sectional view of the semiconductor unit included in the semiconductor device. Note that FIG. 3 depicts a case where a first connection terminal 22, a second connection terminal 23, and an output terminal 24 have been connected to a semiconductor unit 10. FIG. 4 is a cross-sectional view taken along dashed-dotted line X-X in FIG. 3.

The semiconductor unit 10 includes an insulated circuit board 11, semiconductor chips 12a and 12b, and lead frames 13a and 13b. The semiconductor chips 12a and 12b are bonded to the insulated circuit board 11 via solder layers. The lead frames 13a and 13b are also bonded to the semiconductor chips 12a and 12b, respectively, via solder layers.

The insulated circuit board 11 includes an insulating board 11a, wiring plates 11b1, 11b2, and 11c, and a metal plate 11d. The insulating board 11a and the metal plate 11d are rectangular in plan view. The insulating board 11a and the metal plate 11d may have R- or C-chamfered corners. In plan view, the metal plate 11d is smaller in size than the insulating board 11a and is formed inside the insulating board 11a.

The insulating board 11a is made of a material that is electrically insulating and has superior thermal conductivity. Such insulating board 11a may be made of a ceramic or an insulating resin. Example ceramics include aluminum oxide, aluminum nitride, and silicon nitride. Example insulating resins include a paper phenol substrate, a paper epoxy substrate, a glass composite substrate, and a glass epoxy substrate.

The wiring plates 11b1, 11b2, and 11c are formed on the front surface of the insulating board 11a. The wiring plates 11b1, 11b2, and 11c are made of a metal with superior electrical conductivity containing copper. One example of such metal is an alloy containing aluminum in addition to copper.

The wiring plate 11b2 occupies a region that extends across an entire range from the −Y direction edge to the +Y direction edge in the +X direction-side half of the front surface of the insulating board 11a. The wiring plate 11b1 occupies the −X direction-side half of the front surface of the insulating board 11a. The wiring plate 11c is formed from the +Y direction edge toward the −Y direction edge, but with a gap from the −Y direction edge of the insulating board 11a. The wiring plate 11c occupies an area surrounded by the wiring plates 11b1 and 11b2 on the front surface of the insulating board 11a.

The wiring plates 11b1, 11b2, and 11c are formed as follows on the front surface of the insulating board 11a. A metal plate is formed on the front surface of the insulating board 11a, and this metal plate is then subjected to a process such as etching to obtain the wiring plates 11b1, 11b2, and 11c of predetermined shapes. Alternatively, the wiring plates 11b1, 11b2, and 11c that have been cut out from a metal plate in advance may be pressure bonded onto the front surface of the insulating board 11a. Note that the wiring plates 11b1, 11b2, and 11c are mere examples. The number, shapes, sizes, and positions of the wiring plates may be selected as appropriate.

The metal plate 11d is formed on the rear surface of the insulating board 11a. The metal plate 11d is rectangular in shape. In plan view, the metal plate 11d has a smaller area than the insulating board 11a, but is larger than the area of the region where the wiring plates 11b1, 11b2, and 11c are formed. The metal plate 11d may have R- or C-chamfered corners. As one example, the metal plate 11d is formed on the entire surface of the insulating board 11a except for the edges. The metal plate 11d has a metal with superior thermal conductivity as a main component. Example metals are copper, aluminum, and an alloy containing at least one of these metals.

As examples of the insulated circuit board 11 with the configuration described above, it is possible to use a direct copper bonding (DCB) board, an active metal brazed (AMB) board, or an insulating resin board. The insulated circuit board 11 may be attached to the front surface of the top plate 31 of the cooling device 3 via a bonding member (not illustrated). Heat generated at the semiconductor chips 12a and 12b may be transmitted via the wiring plates 11b1 and 11b2, the insulating board 11a, and the metal plate 11d to the cooling device 3 where it is dissipated.

The semiconductor chips 12a and 12b include power device elements made of silicon. The power device elements are RC-IGBT. An RC-IGBT combines the functions of an IGBT, which is a switching element, and a freewheeling diode (FWD), which is a diode element.

The front surface of the semiconductor chip 12a is rectangular in shape in plan view. A gate electrode 12al and an emitter electrode 12a2 (or output electrode), which is a main electrode, are provided on this front surface. In this example, the gate electrode 12al is provided close to and along one short side of the front surface of the semiconductor chip 12a. The gate electrode 12al is connected via a bonding wire 26 to an electrode connected to one of the control terminals 25. The emitter electrode 12a2 is provided close to the other short side of the front surface of the semiconductor chip 12a. The rear surface of the semiconductor chip 12a is provided with a collector electrode 12a3 (or input electrode), which is also a main electrode.

The semiconductor chip 12b has the same configuration as the semiconductor chip 12a, with a gate electrode 12b1 and an emitter electrode 12b2 provided on the front surface of the semiconductor chip 12b and a collector electrode (not illustrated) provided on the rear surface of the semiconductor chip 12b.

The lead frame 13a connects the emitter electrode 12a2 on the front surface of the semiconductor chip 12a and the wiring plate 11c. The lead frame 13a is bonded to the emitter electrode 12a2 via a solder layer 14a. A second connection terminal 23 is connected to the wiring plate 11c. On the other hand, the lead frame 13b connects the emitter electrode 12b2 on the front surface of the semiconductor chip 12b and the wiring plate 11b1. The lead frame 13b is bonded to the emitter electrode 12b2 of the semiconductor chip 12b via a solder layer (not illustrated). An output terminal 24 is connected to the wiring plate 11b1.

The lead frames 13a and 13b are made of a metal with superior electrical conductivity containing copper. As one example, such metal may be an alloy containing aluminum in addition to copper.

The collector electrode 12a3 on the rear surface of the semiconductor chip 12a is bonded via a solder layer 14b to the wiring plate 11b1. The collector electrode on the rear surface of the semiconductor chip 12b is bonded to the wiring plate 11b1 via a solder layer.

With the above configuration, the semiconductor unit 10 constructs a single-phase inverter circuit. The wiring plate 11b2, the semiconductor chip 12b, the lead frame 13b, and the wiring plate 11b1 construct an upper arm of a half-bridge circuit. The wiring plate 11b1, the semiconductor chip 12a, the lead frame 13a, and the wiring plate 11c construct a lower arm of the half-bridge circuit. The upper arm and the lower arm are connected by the wiring plate 11b1, and the output terminals 24 connected to the wiring plate 11b1 is an M terminal acting as an output terminal of the half-bridge circuit. The first connection terminal 22 connected to the wiring plate 11b2 is a P terminal acting as the positive-side input terminal of the half-bridge circuit, and the second connection terminal 23 connected to the wiring plate 11c is an N terminal acting as the negative-side output terminal of the half-bridge circuit. Switching operations of the semiconductor chips 12a and 12b are controlled according to control signals input from the control terminals 25 into the gate electrodes 12al and 12b1.

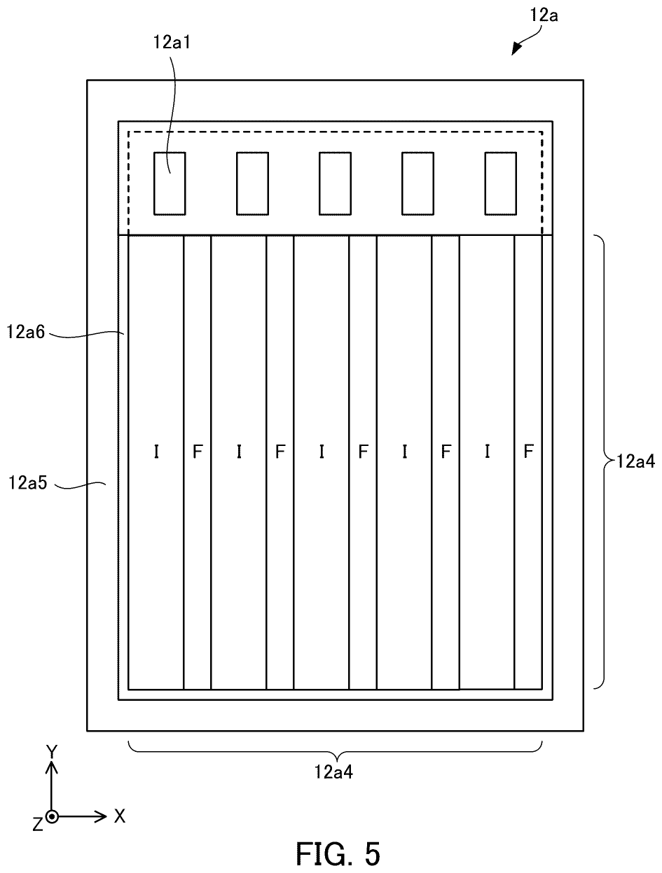

Next, the configuration of the semiconductor chips 12a and 12b will be described further with reference to FIG. 5. FIG. 5 is a plan view of a semiconductor chip.

The semiconductor chip 12a is provided with an active portion 12a4. The active portion 12a4 is a region where the main current flows between the front surface and the rear surface of the semiconductor chip 12a when the semiconductor device 1 is in operation. Note that the emitter electrode 12a2 is provided on the front surface of the active portion 12a4, but has been omitted from FIG. 5.

The active portion 12a4 is provided with transistor regions I including transistor elements (IGBT) and diode regions F including diode elements (FWD). In the example in FIG. 5, the transistor regions I and the diode regions F are alternately arranged in the X direction. Each transistor region I has a P+ type collector region in a region in contact with the rear surface of the semiconductor chip 12a. Each diode region F has an N+ type cathode region in a region in contact with the rear surface of the semiconductor chip 12a. In this specification, regions where a collector region is provided are referred to as “transistor regions I”. That is, a transistor region I is a region that overlaps a collector region in plan view. On the front surface side of each transistor region I, an N-type emitter region, a P-type base region, and a gate structure including a gate conductive portion and a gate insulating film are cyclically arranged in that order.

The gate electrode 12al provided on the front surface of the semiconductor chip 12a is electrically connected to a conductive portion of a gate trench portion of the active portion 12a4. Note that aside from the gate electrode 12al into which a gate control signal is input, electrodes for current detection and temperature detection may also be provided on the front surface of the semiconductor chip 12a.

The semiconductor chip 12a also includes a withstand voltage structure 12a5 provided around the outer periphery of the active portion 12a4. The withstand voltage structure 12a5 alleviates electrolytic concentration on the front surface side of the semiconductor chip 12a. The withstand voltage structure 12a5 may include a guard ring 12a6. The guard ring 12a6 is a P-type region in contact with the front surface of the semiconductor chip 12a.

Although FIG. 5 depicts an example configuration of the semiconductor chip 12a, the semiconductor chip 12b also has the same configuration as the semiconductor chip 12a.

The front surfaces of the semiconductor chips 12a and 12b and the lead frames 13a and 13b are connected, respectively, via solder layers. The rear surfaces of the semiconductor chips 12a and 12b and the wiring plates 11b1 and 11b2 are also connected, respectively, via solder layers. Electromigration may occur in these solder layers.

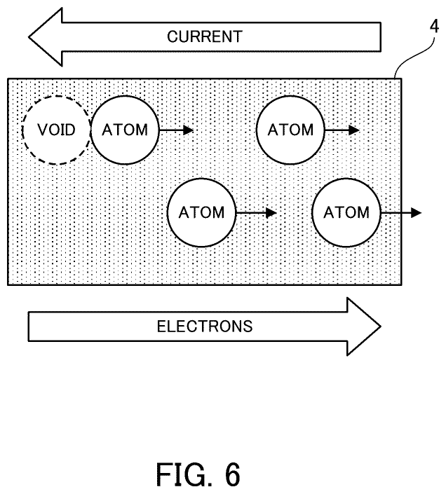

FIG. 6 is a diagram useful in explaining electromigration.

Electromigration is a phenomenon where metal atoms move in a conductor when a current flows through the conductor. As depicted in FIG. 6, when a current flows through the conductor 4, electrons move in the opposite direction to the current. When this happens, metal atoms collide with electrons and move in the same direction as the electrons. Voids are generated in the wake of the moving metal atoms, with large numbers of voids producing cracks. When voids or cracks are produced, there is an increase in thermal resistance and/or wiring resistance, which may result in a rise in temperature and/or impaired electrical conductivity.

The main causes of electromigration are high temperatures and high current densities. In recent years, the miniaturization of power modules like the semiconductor device 1 described above has tended to increase the temperature and current density at bonded parts of semiconductor chips, creating concern that electromigration may occur at such bonded parts. In more detail, for the semiconductor device 1 described above, electromigration occurs in the solder layers that join the front surfaces (the active portion 12a4) of the semiconductor chips 12a and 12b and the lead frames 13a and 13b and the solder layers that join the rear surfaces of the semiconductor chips 12a and 12b and the wiring plates 11b1 and 11b2. In these solder layers, copper atoms included in the lead frames 13a and 13b and the wiring plates 11b1 and 11b2 move through the solder layers to form alloy layers, which are composed of the copper that has moved and the tin included in the solder layer, within the solder layers. Electromigration occurs not only in the solder layers but also in the alloy layers within the solder layers and at interfaces between the solder layers and the lead frames 13a and 13b and wiring plates 11b1 and 11b2. At such locations also, voids are generated in the wake of the copper that has moved, resulting in increased thermal resistance and wiring resistance. In the lead frames 13a and 13b and the wiring plates 11b1 and 11b2 also, voids are generated in the wake of the moving copper atoms, resulting in increased thermal resistance and wiring resistance.

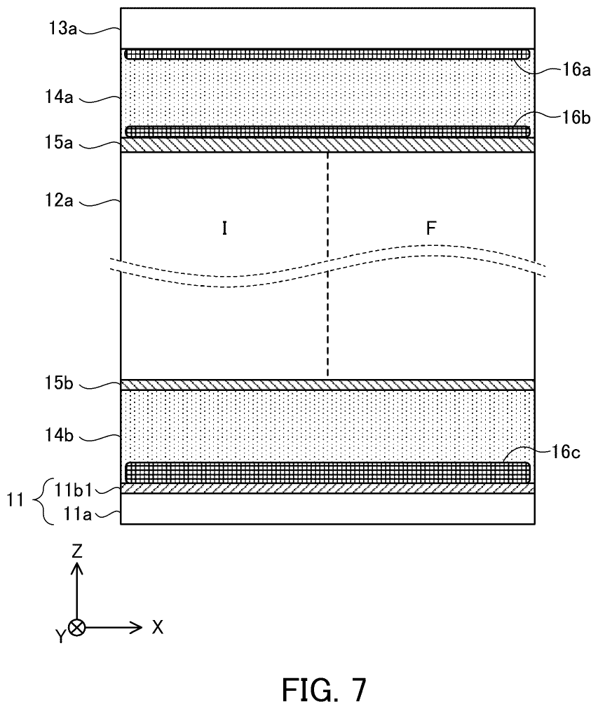

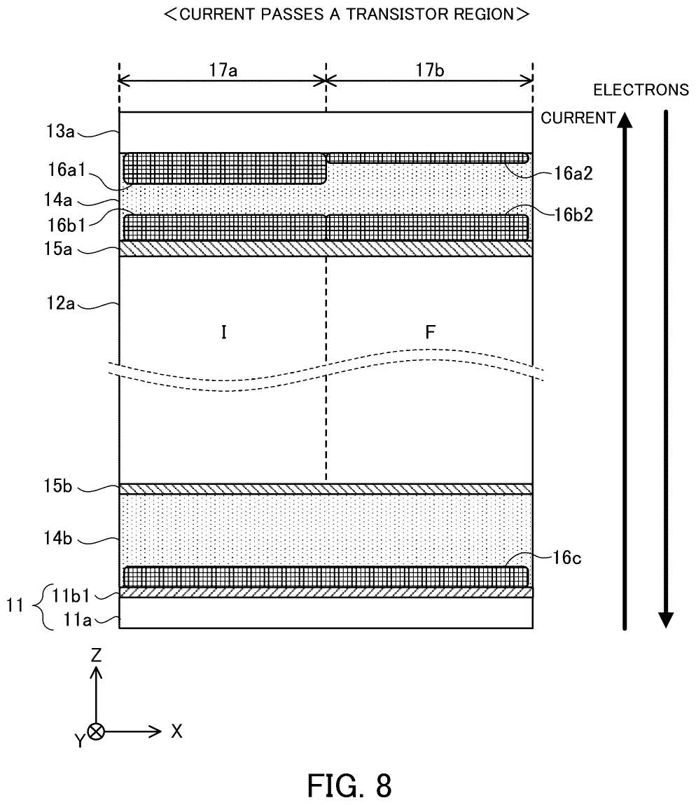

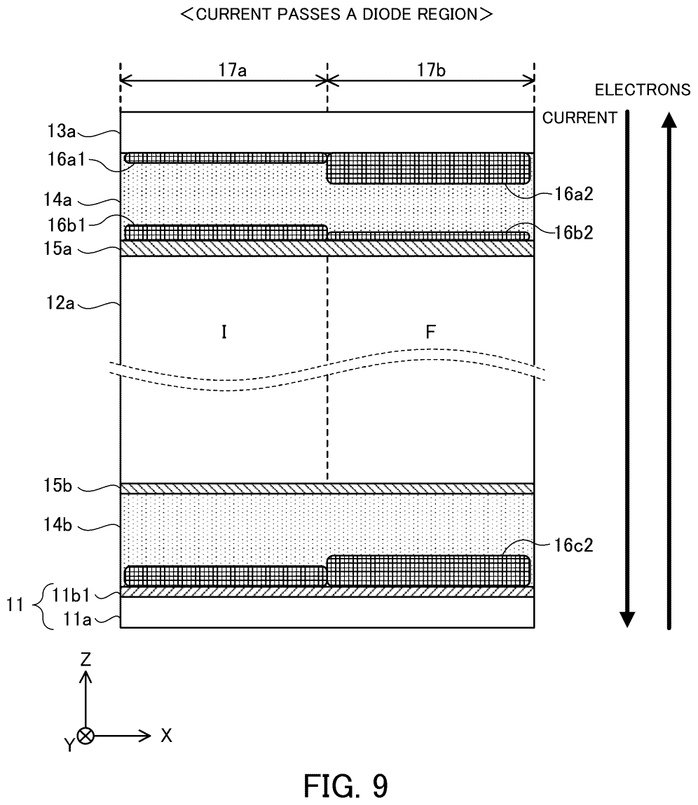

A comparative example of a cross-sectional configuration of the semiconductor unit 10 included in the semiconductor device 1 will now be described with reference to FIG. 7, and an example of how alloy layers are formed in this comparative example will be described with reference to FIGS. 8 and 9.

FIG. 7 depicts a comparative example of a cross-sectional structure of the semiconductor unit. FIG. 7 depicts a partial cross section taken along dashed-dotted line Y-Y in FIG. 3.

First, the laminated structures on the front surface and the rear surface of the semiconductor chip 12a will be described. The emitter electrode 12a2 (see FIGS. 3 and 4) formed on the front surface of the semiconductor chip 12a is coated with a plating layer 15a (or “third plating layer”). The collector electrode 12a3 (see FIG. 4) formed on the rear surface of the semiconductor chip 12a is also coated with a plating layer 15b (or “fourth plating layer”). The plating layers 15a and 15b have nickel or an alloy containing nickel (such as a nickel-phosphorous alloy) as a main component. However, the plating material that constructs the plating layers 15a and 15b does not contain tin. Note that since the shape of the semiconductor chip 12a becomes downwardly convex due to the heat applied during plating and bonding, the thickness of the plating layer 15a is thicker than the plating layer 15b.

On the front surface side of the semiconductor chip 12a, the lead frame 13a and the plating layer 15a are bonded via the solder layer 14a (or “first solder layer”). On the other hand, on the rear surface side of the semiconductor chip 12a, the wiring plate 11b1 of the insulated circuit board 11 and the plating layer 15b are bonded via the solder layer 14b (or “second solder layer”). The solder material constructing the solder layers 14a and 14b has an alloy containing tin as a main component. The lead frame 13a and the wiring plate 11b1 are made of an alloy containing copper (such as a copper-aluminum alloy).

Here, when bonding the lead frame 13a and the plating layer 15a using the solder layer 14a, a tin-copper alloy layer 16a (or intermetallic compound (IMC) layer), which is a reaction layer, is formed between the bonding interface of the lead frame 13a and the bonding interface of the solder layer 14a due to an interfacial reaction between the molten solder material and the copper base material of the lead frame 13a. At this time, a tin-copper alloy layer 16b may also be formed between the bonding interface of the plating layer 15a and the bonding interface of the solder layer 14a due to copper atoms being diffused by thermomigration.

In the same way, when bonding the wiring plate 11b1 and the plating layer 15b using the solder layer 14b, a tin-copper alloy layer 16c (or IMC layer), which is a reaction layer, is formed between the bonding interface of the wiring plate 11b1 and the bonding interface of the solder layer 14b due to an interfacial reaction between the molten solder material and the copper base material of the wiring plate 11b1. These tin-copper alloy layers 16a to 16c are brittle, especially when thick. As one example, when stress is generated at a bonding interface due to thermal cycles or ΔTjP/C, cracking may occur in the tin-copper alloy layers 16a to 16c and there is the risk of peeling occurring due to crack extension.

Next, the state of the tin-copper alloy layers 16a to 16c when passing a current will be described with reference to FIGS. 8 and 9.

FIG. 8 is a first diagram depicting one example of formation of a tin-copper alloy layer in the comparative example. FIG. 8 depicts one example of how the state of the tin-copper alloy layers 16a to 16c changes when a current passes a transistor region I of the semiconductor chip 12a for the comparative example in FIG. 7. When a transistor region I passes a current, the current flows upward in FIG. 8 (that is, in the +Z direction), and electrons move downward in FIG. 8 (that is, in the −Z direction).

At this time, in a region 17a of the solder layer 14a facing a transistor region I (that is, a region that overlaps a transistor region I in plan view), copper atoms move from the lead frame 13a due to electromigration and react with the tin in the solder layer 14a. As a result, out of the tin-copper alloy layer 16a, a partial alloy layer 16al corresponding to the region 17a grows and becomes thicker. This partial alloy layer 16al also grows due to the movement of copper atoms included in the partial alloy layer 16al. In addition, in the region 17a of the solder layer 14a, copper atoms of the lead frame 13a and/or the partial alloy layer 16al are transported toward the semiconductor chip 12a by electromigration. As a result, out of the tin-copper alloy layer 16b, a partial alloy layer 16b1 corresponding to the region 17a also grows and becomes thicker. Together with this, it is conceivable that the number of voids in the lead frame 13a, at a bonding interface between the lead frame 13a and the solder layer 14a, and in the partial alloy layers 16al and 16b1 will increase.

As described above, due to the occurrence of electromigration that accompanies the passing of current, a tin-copper alloy layer grows and becomes thicker in the solder layer 14a, which makes cracking more likely to occur. There are problems of increased thermal resistance and wiring resistance in the region 17a due to the occurrence of cracks in the tin-copper alloy layer and large numbers of voids being produced in the lead frame 13a, the solder layer 14a, and the partial alloy layers 16al and 16b1.

Note that out of the tin-copper alloy layer 16b, the partial alloy layer 16b2 corresponding to the region 17b that faces a diode region F (that is, a region that overlaps a diode region F in plan view) grows and becomes thicker due to copper atoms being diffused by thermomigration. Accordingly, cracking and voids are likely to occur in the region 17b as well as in the region 17a.

FIG. 9 is a second diagram depicting one example of formation of a tin-copper alloy layer in the comparative example. FIG. 9 depicts one example of how the state of the tin-copper alloy layers 16a to 16c changes when a current passes a diode region F of the semiconductor chip 12a for the comparative example in FIG. 7. When a diode region F passes a current, the current flows downward in FIG. 9 (that is, in the −Z direction), and electrons move upward in FIG. 9 (that is, in the +Z direction).

At this time, in a region 17b of the solder layer 14b facing a diode region F (that is, a region that overlaps a diode region F in plan view), copper atoms move from the wiring plate 11b1 due to electromigration and react with the tin atoms in the solder layer 14b. As a result, out of the tin-copper alloy layer 16c, a partial alloy layer 16c2 corresponding to the region 17b grows and becomes thicker, which makes cracking likely. This partial alloy layer 16c2 also grows due to the movement of copper atoms included in the partial alloy layer 16c2. Together with this, it is conceivable that the number of voids in the wiring plate 11b1, at the bonding interface between the wiring plate 11b1 and the solder layer 14b, and in the partial alloy layer 16c2 will increase. There are problems of increased thermal resistance and wiring resistance in the region 17b due to the occurrence of cracks in the tin-copper alloy layer and large numbers of voids being produced in the wiring plate 11b1, the solder layer 14b, and the partial alloy layer 16c2.

Note that that even in the region 17b of the solder layer 14a that faces a diode region F, copper atoms are transported, albeit in a small amount, by electromigration from the partial alloy layer 16b2 toward the lead frame 13a. As a result, out of the tin-copper alloy layer 16a, the partial alloy layer 16a2 corresponding to the region 17b grows and becomes thicker. Out of the solder layer 14a, copper atoms are also diffused due to thermomigration in the region 17a that faces a transistor region I. As a result, out of the tin-copper alloy layer 16b, the partial alloy layer 16b1 corresponding to the region 17a grows and becomes thicker. Accordingly, cracking and voids are likely to occur in the region 17a as well as in the region 17b.

As described above, current flows in both directions in the semiconductor chip 12a that includes an RC-IGBT. This means that electromigration occurs in both the solder layer 14a on the front surface side and in the solder layer 14b on the rear surface side of the semiconductor chip 12a, so that thermal resistance and wiring resistance may increase on the front side and on the rear side of the semiconductor chips 12a.

To solve this problem, in the present embodiment, at least the surface of the lead frame 13a that is to be bonded to the front surface of the semiconductor chip 12a and the surface of the wiring plate 11b1 that is to be bonded to the rear surface of the semiconductor chip 12a are coated with a plating layer containing nickel. By doing so, the occurrence of the electromigration phenomenon, where copper atoms in the solder layers 14a and 14b move, may be suppressed, thereby suppressing the expansion of a tin-copper alloy layer and the production of large numbers of voids in the solder layers, the alloy layers, the lead frame 13a, and the wiring plate 11b1. As a result, increases in thermal resistance and wiring resistance may be prevented, and the long-term reliability of the semiconductor device 1 may be improved.

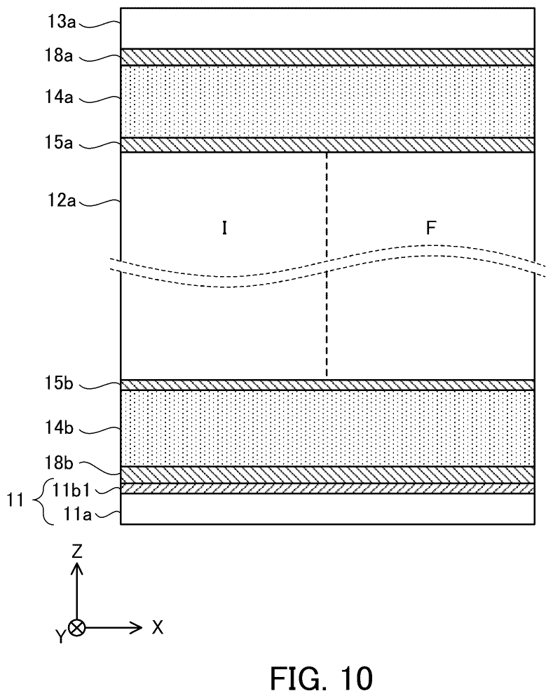

Example configurations of the semiconductor unit 10 according to the present embodiment will now be described with reference to FIGS. 10 to 14.

FIG. 10 depicts a first example of formation of plating layers in the semiconductor unit. In the example in FIG. 10, a plating layer 18a (or “first plating layer”) and a plating layer 18b (or “second plating layer”) are added to the comparative example in FIG. 7. That is, the semiconductor chip 12a-side surface of the lead frame 13a is coated with the plating layer 18a. The surface of the wiring plate 11b1 (or “wiring layer”) is coated with the plating layer 18b. The plating layers 18a and 18b have nickel or an alloy containing nickel (such as a nickel-phosphorous alloy) as a main component. However, the plating material constructing the plating layers 18a and 18b does not contain tin.

By forming the plating layer 18a as described above, it becomes difficult for copper atoms in the lead frame 13a to move to the solder layer 14a when the transistor region I passes a current, thereby reducing the risk of electromigration occurring in the solder layer 14a. By also forming the plating layer 18b as described above, it becomes difficult for copper atoms in the wiring plate 11b1 to move to the solder layer 14b when the diode region F passes a current, thereby reducing the risk of electromigration occurring in the solder layer 14b. As a result, the generation and expansion of a tin-copper alloy layer in the solder layers 14a and 14b are suppressed, and the production of voids in the solder layers 14a and 14b, the alloy layers, the lead frame 13a, and the wiring plate 11b1 is suppressed, which reduce any increase in thermal resistance and wiring resistance. Accordingly, the long-term reliability of the semiconductor device 1 may be improved.

During formation of the solder layers 14a and 14b also, it is possible to reduce the risk of diffusion of copper atoms into the solder layers 14a and 14b due to thermomigration. As a result, the movement and expansion of the tin-copper alloy layer in the solder layers 14a and 14b are suppressed, and the production of voids in the solder layers 14a and 14b, the alloy layers, the lead frame 13a, and the wiring plate 11b1 is suppressed, which reduce any increase in thermal resistance and wiring resistance.

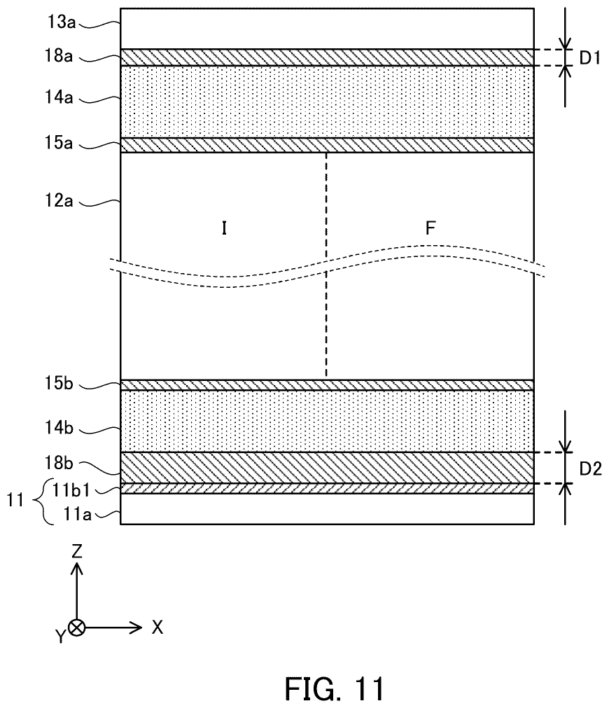

FIG. 11 depicts a second example of formation of plating layers in the semiconductor unit. In the example in FIG. 11, the plating layers 18a and 18b are formed so that a thickness D2 of the plating layer 18b is larger than a thickness D1 of the plating layer 18a in comparison to FIG. 10. As one example, when the thickness of the semiconductor chip 12a is around 50 μm or greater and 100 μm or lower, the thickness D2 of the plating layer 18b may be several tens of μm and the thickness D1 of the plating layer 18a may be ½ or more and around ⅓ or less of the thickness D2.

In the semiconductor chip 12a, the current density in a diode region F is higher than the current density in a transistor region I. This means that the amount of the movement of copper atoms from the wiring plate 11b1 to the solder layer 14b when a diode region F passes a current is greater than the amount of the movement of copper atoms from the lead frame 13a to the solder layer 14a when a transistor region I passes a current. As a result, thermal resistance and wiring resistance due to electromigration are more likely to increase when a diode region F passes a current than when a transistor region I passes a current.

By making the thickness D2 of the plating layer 18b larger than the thickness D1 of the plating layer 18a as depicted in FIG. 11, the effect of suppressing electromigration when the diode region F passes a current may be increased. As a result, increases in thermal resistance and wiring resistance may be more reliably prevented.

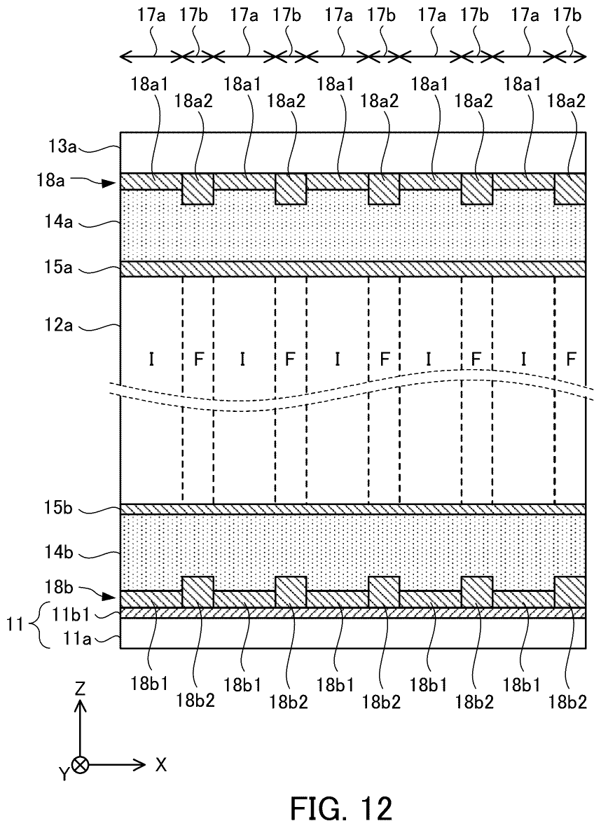

FIG. 12 depicts a third example of formation of plating layers in the semiconductor unit.

In the example in FIG. 12, out of the plating layer 18a, a partial plating layer 18al in a region 17a (or “first region”) facing a transistor region I and a partial plating layer 18a2 in a region 17b (or “second region”) facing a diode region F are constructed with different thicknesses. In more detail, each partial plating layer 18a2 corresponding to a diode region F is formed thicker than each partial plating layer 18al corresponding to a transistor region I.

Also, out of the plating layer 18b in FIG. 12, the partial plating layer 18b1 in a region 17a (or “third region”) facing a transistor region I and the partial plating layer 18b2 in a region 17b (or “fourth region”) facing a diode region F are constructed with different thicknesses. In more detail, a partial plating layer 18b2 corresponding to a diode region F is formed thicker than a partial plating layer 18b1 corresponding to a transistor region I.

As described earlier, in the semiconductor chip 12a, the current density in a diode region F is higher than the current density in a transistor region I. By making the thickness of a plating layer corresponding to a diode region F thicker than the thickness of a plating layer corresponding to a transistor region I as depicted in FIG. 12, the effect of suppressing electromigration when a diode region F passes a current is increased. As a result, it is possible to more reliably prevent any increase in thermal resistance and wiring resistance in both the regions 17a and 17b.

When the plating layers 18a and 18b have these thicknesses, during formation of the solder layers 14a and 14b also, diffusion of copper atoms due to thermomigration is less likely to occur in the regions 17b corresponding to the diode regions F compared to the regions 17a corresponding to the transistor regions I, out of the solder layers 14a and 14b. This means that it is harder for a tin-copper alloy layer to form in the regions 17b compared with in the regions 17a. Accordingly, after the semiconductor chip 12a starts passing currents, out of the solder layers 14a and 14b, a longer time is taken for a tin-copper alloy layer to grow large in the regions 17b corresponding to the diode regions F compared with in the regions 17a corresponding to the transistor regions I. As a result, the time taken for thermal resistance and wiring resistance to increase to a level where they affect the characteristics of the semiconductor device 1 may be extended, which means the reliability of the semiconductor device 1 may be improved.

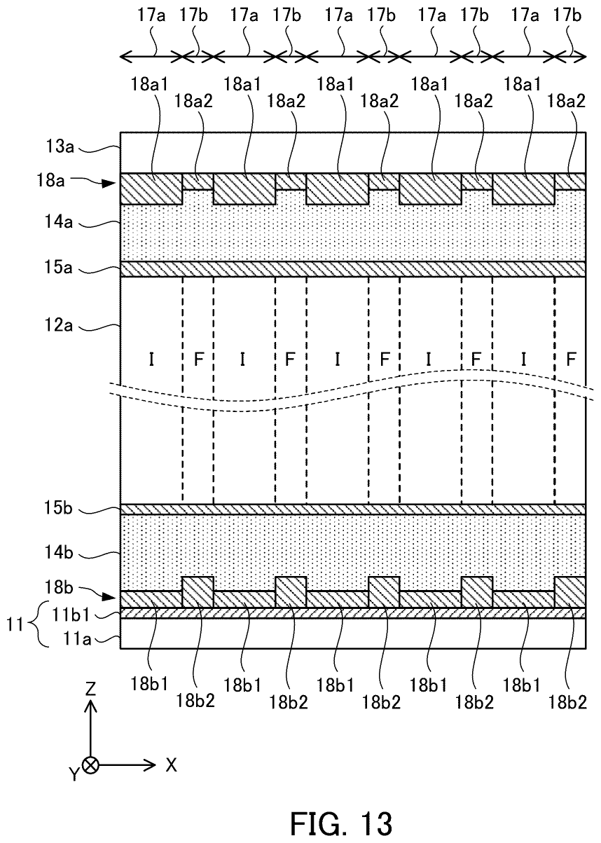

FIG. 13 depicts a fourth example of formation of plating layers in the semiconductor unit.

In the example in FIG. 13, in the same way as in FIG. 12, out of the plating layer 18a, a partial plating layer 18al in a region 17a facing a transistor region I and a partial plating layer 18a2 in a region 17b facing a diode region F are constructed with different thicknesses. However, unlike FIG. 12, a partial plating layer 18al corresponding to a transistor region I is formed thicker than a partial plating layer 18a2 corresponding to a diode region F. On the other hand, in the same way as in FIG. 12, out of the plating layer 18b, a partial plating layer 18b2 corresponding to a diode region F is formed thicker than a partial plating layer 18b1 corresponding to a transistor region I.

As depicted in FIG. 8, when a transistor region I passes a current, electrons move downward in FIG. 8 (that is, in the −Z direction). For this reason, electromigration is observed as a phenomenon where copper atoms included in the lead frame 13a move to the solder layer 14a. By forming each partial plating layer 18al in the plating layer 18a corresponding to a transistor region I thicker than each partial plating layer 18a2 corresponding to a diode region F as depicted in FIG. 13, it is possible to make it difficult for copper atoms to move from the lead frame 13a to the solder layer 14a.

Also, as depicted in FIG. 9, when a diode region F passes a current, electrons move upward in FIG. 9 (that is, in the +Z direction). For this reason, electromigration is observed as a phenomenon where copper atoms included in the wiring plate 11b1 move to the solder layer 14b. By forming each partial plating layer 18b2 in the plating layer 18b corresponding to a diode region F thicker than a partial plating layer 18b1 corresponding to a transistor region I as depicted in FIG. 13, it is possible to make it difficult for copper atoms to move from the wiring plate 11b1 to the solder layer 14b.

Accordingly, by using the configuration in FIG. 13, it is possible to suppress the occurrence of electromigration, and thereby more reliably prevent increases in thermal resistance and wiring resistance in the regions 17a and 17b.

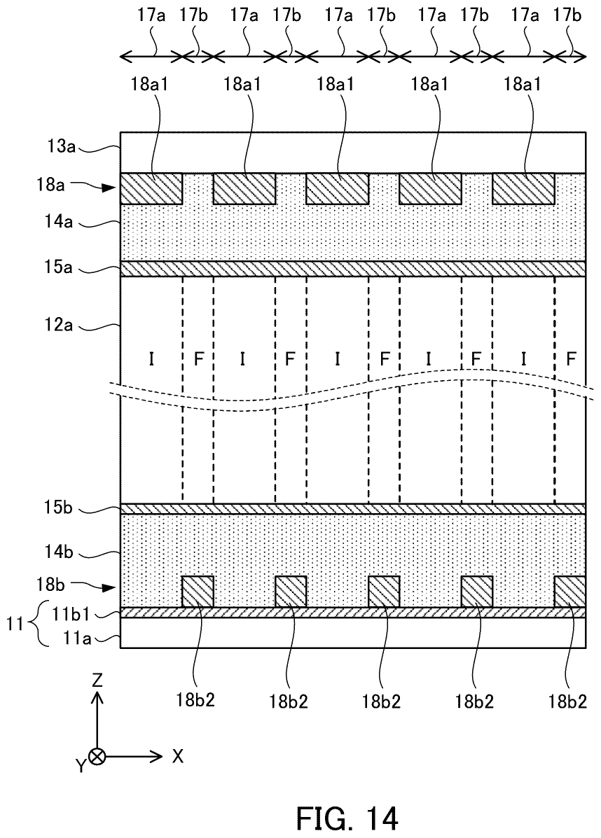

FIG. 14 depicts a fifth example of formation of plating layers in the semiconductor unit.

In the example in FIG. 14, the plating layer 18a is not formed over the entire surface of the lead frame 13a, and partial plating layers 18al are formed in only regions 17a that face transistor regions I. Likewise, the plating layer 18b is not formed on the entire surface of the wiring plate 11b1, and partial plating layers 18b2 are formed in only regions 17b that face diode regions F.

As described above, when a transistor region I passes a current, electromigration is observed as a phenomenon where copper atoms included in the lead frame 13a move to the solder layer 14a. By forming the partial plating layers 18al in only the regions 17a facing the transistor regions I as depicted in FIG. 14, it is possible to make it difficult for copper atoms to migrate from the lead frame 13a to the solder layer 14a.

Also as described above, when a diode region F passes a current, electromigration is observed as a phenomenon where copper atoms included in the wiring plate 11b1 move to the solder layer 14b. By forming the partial plating layers 18b2 in only regions 17b that face the diode regions F as depicted in FIG. 14, it is possible to make it difficult for copper atoms to migrate from the wiring plate 11b1 to the solder layer 14b.

Accordingly, the configuration in FIG. 14 makes it possible to suppress the occurrence of electromigration, and thereby more reliably prevent any increase in thermal resistance and wiring resistance in the regions 17a and 17b.

Although laminated structures on both surfaces of the semiconductor chip 12a have been described using FIGS. 10 to 14, the laminated structures on both surfaces of the semiconductor chip 12b may have the same structures.

According to an aspect of the present disclosure, the occurrence of electromigration in solder layers is suppressed, thereby improving the long-term reliability of a semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip having an upper surface and a lower surface opposite to each other, and including transistor regions and diode regions that are arranged alternately with one another in a direction along the upper surface and the lower surface;
a lead frame that contains copper and is disposed on the upper surface of the semiconductor chip;
a first plating layer that contains nickel and is disposed on a semiconductor chip-side surface of the lead frame;
a first solder layer that contains tin and bonds the upper surface of the semiconductor chip to the first plating layer;
an insulated circuit board that is disposed on the lower surface of the semiconductor chip and has a wiring layer, which contains copper, disposed on a semiconductor chip-side surface thereof;
a second plating layer that contains nickel and is disposed on a semiconductor chip-side surface of the wiring layer; and
a second solder layer that contains tin and bonds the lower surface of the semiconductor chip to the second plating layer.

2. The semiconductor device according to claim 1, wherein a thickness of the second plating layer is greater than a thickness of the first plating layer.

3. The semiconductor device according to claim 1, wherein
in the first plating layer, a thickness of first regions on a semiconductor chip-side surface of the lead frame differs from a thickness of second regions, the first regions respectively facing respective ones of the transistor regions, the second regions respectively facing respective ones of the diode regions, and
in the second plating layer, a thickness of third regions on a semiconductor chip-side surface of the insulated circuit board differs from a thickness of fourth regions, the third regions respectively facing respective ones of the transistor regions, the fourth regions respectively facing respective ones of the diode regions.

4. The semiconductor device according to claim 3, wherein
in the first plating layer, the thickness of the second regions is greater than the thickness of the first regions, and
in the second plating layer, the thickness of the fourth regions is greater than the thickness of the third regions.

5. The semiconductor device according to claim 4, wherein in the semiconductor chip, a current density when a current is passed is higher in the diode regions than in the transistor regions.

6. The semiconductor device according to claim 3, wherein
in the first plating layer, the thickness of the first regions is greater than the thickness of the second regions, and
in the second plating layer, the thickness of the fourth regions is greater than the thickness of the third regions.

7. The semiconductor device according to claim 3, wherein
the first plating layer is disposed in only the first regions, at the semiconductor chip-side surface of the lead frame, and
the second plating layer is disposed in only the fourth regions, at the semiconductor chip-side surface of the insulated circuit board.

8. The semiconductor device according to claim 1, wherein
the lead frame is connected to an emitter electrode of the semiconductor chip via the first solder layer, and
the wiring layer of the insulated circuit board is connected to a collector electrode of the semiconductor chip via the second solder layer.

9. The semiconductor device according to claim 8, further comprising:
a third plating layer that contains nickel and is disposed on a surface that faces the first solder layer on the upper surface of the semiconductor chip; and
a fourth plating layer that contains nickel and is disposed on a surface that faces the second solder layer on the lower surface of the semiconductor chip.
